(19) United States
(12) Patent Application Publication
(10) Pub. No.: US 2023/0268419 A1
(43) Pub. Date: Aug. 24, 2023

(54) DEVICES HAVING A TRANSISTOR WITH A MODIFIED CHANNEL REGION

(71) Applicants: Haitao Liu, Boise, ID (US); Naveen Kaushik, Boise, ID (US); Chittoor Ranganathan Parthasarathy, Manikonda (IN); Deepak Chandra Pandey, Hazel Grove (GB)

(72) Inventors: Haitao Liu, Boise, ID (US); Naveen Kaushik, Boise, ID (US); Chittoor Ranganathan Parthasarathy, Manikonda (IN); Deepak Chandra Pandey, Hazel Grove (GB)

(21) Appl. No.: 17/874,985

(22) Filed: Jul. 27, 2022

(30) Foreign Application Priority Data
Feb. 23, 2022 (IN) 202211009640

(51) Int. Cl. H01L 29/66; H01L 29/06; H01L 29/16; H01L 21/02; H01L 21/308

(52) U.S. Cl. CPC H01L 29/6659; H01L 21/0206; H01L 21/02293; H01L 21/3086; H01L 29/0638; H01L 29/0649; H01L 29/16

(57) ABSTRACT

A variety of applications can include apparatus having a transistor comprising a modified channel region to address sub-surface leakage issues of the transistor. A dielectric region can be structured to extend from a channel structure of the transistor downward into the substrate for the transistor, with the dielectric region disposed between the source of the transistor and the drain of the transistor to reduce leakage current paths between the source and the drain. The dielectric region can be structured with only dielectric material or with crystalline semiconductor material surrounded by dielectric material.

### PRIORITY APPLICATION

This application claims the benefit of priority to Indian Patent Application Serial Number 202211009640, filed Feb. 23, 2022, which is incorporated herein by reference in its entirety.

### FIELD OF THE DISCLOSURE

Embodiments of the disclosure relate generally to electronic devices and systems and, more specifically, to transistors of electronic devices and systems and formation thereof.

### BACKGROUND

Memory devices are typically provided as internal, semiconductor, integrated circuits in computers or other electronic devices. There are many different types of memory, including volatile and non-volatile memory . Volatile memory requires power to maintain its data, and includes random-access memory (RAM), dynamic random-access memory (DRAM), static RAM (SRAM), or synchronous dynamic random-access memory (SDRAM), among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others.

Flash memory is utilized as non-volatile memory for a wide range of electronic applications. Flash memory devices typically include one or more groups of one-transistor, floating gate or charge trap memory cells that allow for high memory densities, high reliability, and low power consumption. Two common types of flash memory array architectures include NAND and NOR architectures, named after the logic form in which the basic memory cell configuration of each is arranged. The memory cells of the memory array are typically arranged in a matrix. In an example, the gates of each floating gate memory cell in a row of the array are coupled to an access line (e.g., a word line). In a NOR architecture, the drains of each memory cell in a column of the array are coupled to a data line (e.g., a bit line). In a NAND architecture, the drains of each memory cell in a string of the array are coupled together in series, source to drain, between a source line and a data line.

Various architectures of memory devices use transistors as memory elements or other components within the memory devices. To increase the area efficiency of a memory device or a memory system, it is desirable to shrink one or more structural features of transistors, such as a metal-oxide-semiconductor field-effect transistor (MOSFET) or equivalent transistor, used within the memory device. Reductions of one or more structural features can be addressed by advances in design and processing of the transistors.

### BRIEF DESCRIPTION OF THE DRAWINGS

The drawings, which are not necessarily drawn to scale, illustrate generally, by way of example, but not by way of limitation, various embodiments discussed in the present document.

FIG. 1 illustrates a cross-sectional representation of an example transistor structure to reduce or eliminate sub-surface conduction, in accordance with various embodiments.

FIG. 2 illustrates a cross-sectional representation of another example transistor structure to reduce or eliminate sub-surface conduction, in accordance with various embodiments.

FIGS. 3 - 13 illustrate features of an example method of forming a transistor, in accordance with various embodiments.

FIGS. 14 - 23 illustrate features of an embodiment of an example method of forming a transistor, in accordance with various embodiments.

FIG. 24 is a flow diagram of features of an example method of forming a transistor, in accordance with various embodiments.

FIG. 25 is a flow diagram of features of an example method of forming a transistor, in accordance with various embodiments.

FIG. 26 is a block diagram illustrating an example of a machine upon which one or more embodiments may be implemented, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

Both NOR and NAND flash architecture semiconductor memory arrays are accessed through decoders that activate specific memory cells by selecting the word line coupled to their gates. In a NOR architecture semiconductor memory array, once activated, the selected memory cells place their data values on bit lines, causing different currents to flow depending on the state at which a particular cell is programmed. In a NAND architecture semiconductor memory array, a high bias voltage is applied to a drain-side select gate (SGD) line. Word lines coupled to the gates of the unselected memory cells of each group are driven at a specified pass voltage (e.g., Vpass) to operate the unselected memory cells of each group as pass transistors (e.g., to pass current in a manner unrestricted by their stored data values). Current then flows between the source line and the bit line through each series coupled group, restricted only by the selected memory cells of each group, placing current encoded data values of selected memory cells on the bit lines.

Each flash memory cell in a NOR or NAND architecture semiconductor memory array can be programmed individually or collectively to one or a number of programmed states. For example, a single-level cell (SLC) can represent one of two programmed states (e.g., 1 or 0), representing one bit of data. Flash memory cells can also represent more than two programmed states, allowing the manufacture of higher density memories without increasing the number of memory cells, as each cell can represent more than one binary digit (e.g., more than one bit). Such cells can be referred to as multi-state memory cells, multi-digit cells, or multi-level cells (MLCs). In certain examples, MLC has been referred to as a memory cell that can store two bits of data per cell (e.g., one of four programmed states). MLC is used herein in its broader context to refer to any memory cell(s) that can store more than one bit of data per cell (i.e., that can represent more than two programmed states). A memory cell that can store two bits of data per cell (e.g., one of four programmed states) can be referred to as a dual-level cell (DLC). A triple-level cell (TLC) refers to a memory cell that can store three bits of data per cell (e.g., one of eight programmed states). A quad-level cell (QLC) can store four bits of data per cell, and a penta-level cell (PLC) can store five bits of data per cell.

To increase the area efficiency of a memory device, it may be desirable to shrink gate lengths of MOSFETs used in the memory device. For example, a memory device can include one or more high voltage (HV) MOSFETs, which are operated at voltages that are high with respect to transistors associated with memory cells of the memory device. However, shrinking a HV MOSFET is challenging due to sub-surface leakage and punch through. Sub-surface leakage is a current flow between a source and a drain along a sub-surface path in the substrate containing the transistor, where the sub-surface path is below a channel path of the transistor that is at the surface separated from a gate structure by dielectric. Though the sub-surface path is operatively more resistive than the channel path, it can provide a leakage current that is undesirable. With the separation of the source and the drain effectively reduced with reduction of the gate length of a MOSFET, the resistance of the sub-surface path reduces, increasing sub-surface leakage current. Adding an additional boron implant can help to suppress the subsurface leakage, but the boron implant can increase the body effect of the HV MOSFET by approximately one volt, which is a significant downside for HV devices. The increase of the body effect can cause I_{OFF} to rise exponentially and can also degrade the subthreshold swing (slope) . The subthreshold swing is the gate voltage to change the drain current by one decade (one order of magnitude).

The current I_{OFF} is the off-state current of the MOSFET, while current I_{ON} is the on-state current. A n-channel MOSFET, for example, is in the off-state when the voltage between the gate and the source of the MOSFET (V_{gs}) is less than the threshold voltage (Vₜ). The subthreshold current, when V_{gs} < Vₜ, is a main contributor to I_{OFF}. Measured I_{OFF} is the drain current (I_{d}) measured at V_{gs} === 0 with the voltage between the drain and the source (V_{ds}) at the level of the supply voltage. The ratio, I_{ON}/I_{OFF}, is a figure of merit for high performance and low leakage power for the transistor. High performance is associated with more I_{ON} and low leakage power is associated with less I_{OFF.} Eliminating or ssignificantly reducing sub-surface conduction can improve the I_{ON}/I_{OFF} ratio.

In various embodiments, a dielectric region can be structured between a drain region and a source region of a transistor, where the dielectric region extends downward from a channel structure between the drain region and the source region. The channel structure can be disposed at a surface below a gate of the transistor and separated from the gate by electrically insulating material referred to as a gate dielectric. The dielectric region between the drain region and the source region below the channel structure provides a barrier to creation of conduction paths between the drain region and the source region, reducing or eliminating sub-surface leakage current. The dielectric region can be structured extending downward into the substrate to a level lower than a level at which the source region extends into the substrate and lower than a level at which the drain region extends into the substrate.

In various embodiments, processes for forming transistors can be modified to address the sub-surface leakage issue. Such processes can be implemented without additional masks. For instance, a gate mask can be used. In addition, such modifications can be aligned with current complementary metal-oxide-semiconductor (CMOS) processing. The electrical properties of the MOSFET, other than the sub-surface leakage electrical properties, processed with a dielectric region to address sub-surface leakage issues do not suffer any penalty (degradation). Reducing the sizes of MOSFET devices such as HV MOSFETs can enable a design path for scaling periphery devices for a memory array of a memory device. Processes for forming transistors to address the sub-surface leakage issue can provide improvement in the I_{ON}/I_{OFF} ratio and improved subthreshold swing.

Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., internet-of things (IoT) devices, etc.), have varying storage needs depending on, among other things, the type of electronic device, use environment, performance expectations, etc. In addition, electronic devices can be broken down into several main components, a processor (e.g., a central processing unit (CPU) or other main processor); memory (e.g., one or more volatile or non-volatile RAM memory devices, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc. Each of these devices can use transistors structured to eliminate sub-surface conduction to improve an I_{ON/}I_{OFF} ratio.

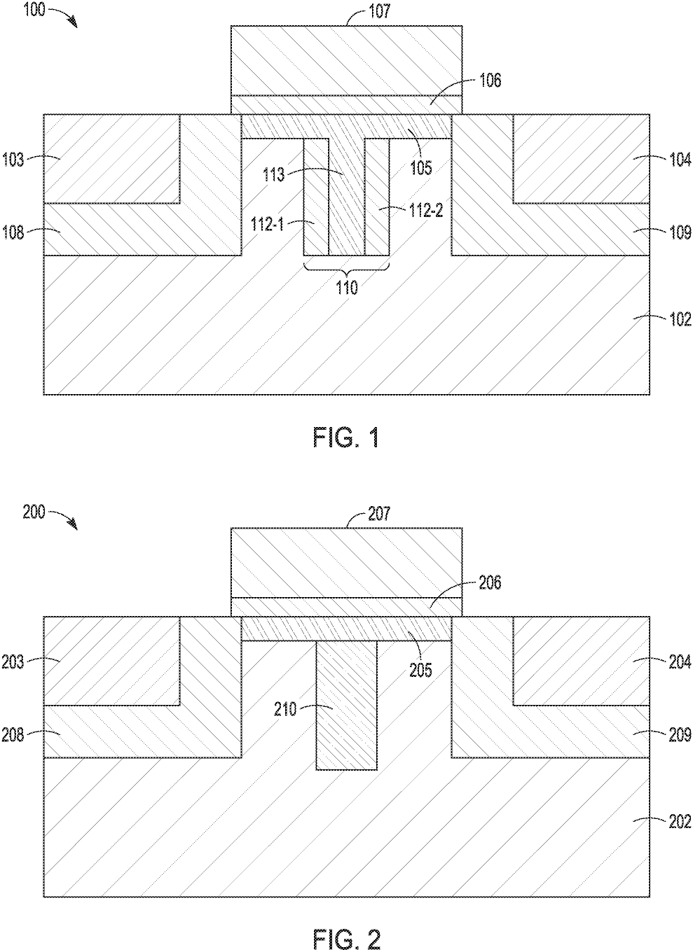

FIG. 1 illustrates a cross-sectional representation of an embodiment of an example transistor structure 100 to reduce or eliminate sub-surface conduction. Transistor structure 100 can include a source 103 and a drain 104 in a substrate 102, with a channel structure 105 to couple source 103 to drain 104. Substrate 102 can be, but is not limited to, a silicon-based substrate. A lightly doped drain (LDD) 108 can be disposed about source 103 and can connect source 103 to channel structure 105. A LDD 109 can be disposed about drain 104 and can connect drain 104 to channel structure 105. Transistor structure 100 can include a gate 107 separated from the channel structure 105 by an insulating region 106. Insulating region 106 operates as a gate dielectric that is a tunnel region. Insulating region 106 can comprise one or more dielectrics. Insulating region 106 can be silicon oxide or a high k dielectric. A high k dielectric is a dielectric having a dielectric constant greater than that of silicon oxide. Insulating region 106 can be a three layer structure including an ONO struture, which is a structure having an oxide, nitride, and an oxide. Gate 107 can be a metal gate or a conductive material different from a metal such as a doped semiconductor, such as but not limited to, doped polysilicon . Conductivity types, such as n-type and p-type, of various regions of transistor structure 100 can depend on the application for transistor structure 100.

A dielectric region 110 can extend from channel structure 105 downward into the substrate 102 and can be disposed between source 103 and drain 104 to reduce leakage current paths between source 103 and drain 104. In some embodiments, dielectric region 110 can be centered with respect to channel structure 105. In other embodiments, dielectric region 110 is not centered with respect to channel structure 105, but is disposed between source 103 and drain 104 and separate from each of source 103 and drain 104. Dielectric region 110 can include a crystalline semiconductor region 113 within dielectric material. Depending on the fabrication, the dielectric material can be realized as multiple dielectric materials 112-1 and 112-2 or as one dielectric material. In either case, crystalline semiconductor region 113 can be completely encompassed within the dielectric materials. Crystalline semiconductor region 113 and dielectric materials 112-1 and 112-2 can be implemented with various materials. Crystalline semiconductor region 113 can include epitaxial silicon, and the dielectric materials 112-1 and 112-2 can include an electrically insulating oxide, such as but not limited to silicon oxide. Crystalline semiconductor region 113 can include recrystallized polysilicon.

Material of the channel structure 105 and material of the crystalline semiconductor region 113 can have a common composition. Channel structure 105 and crystalline semiconductor region 113 can be an epitaxial semiconductor. Channel structure 205 can be a recrystallized poly-semiconductor. For example, channel structure 105 and crystalline semiconductor region 113 can be epitaxial silicon, or channel structure 105 and crystalline semiconductor region 113 can be recrystallized polysilicon. Other semiconductor material, such as but not limited to gallium phosphide (GaP), can be used for channel structure 105 and crystalline semiconductor region 113. Channel structure 105 and crystalline semiconductor region 113 can be of different material compositions.

Dielectric region 110 can extend downward into substrate 102 to a level lower than a level at which source 103 extends into substrate 102 and lower than a level at which drain 104 extends into substrate 102. With dielectric region 110 extending to such a level, a conduction path between source 103 and drain 104 is relatively long having a relatively large resistance substantially reducing or effectively eliminating leakage current.

FIG. 2 illustrates a cross-sectional representation of an embodiment of an example transistor structure 200 to reduce or eliminate sub-surface conduction. Transistor structure 200 can include a source 203 and a drain 204 in a substrate 202, with a channel structure 205 to couple source 203 to the drain 204. Substrate 202 can be, but is not limited to, a silicon-based substrate. A LDD 208 can be disposed about source 203 and can connect source 203 to channel structure 205. A LDD 209 can be disposed about drain 204 and can connect drain 204 to channel structure 205. Transistor structure 200 can include a gate 207 separated from the channel structure 205 by an insulating region 206. Insulating region 206 operates as a gate dielectric that is a tunnel region. Insulating region 206 can comprise one or more dielectrics. Insulating region 206 can be silicon oxide or a high k dielectric. Insulating region 206 can be a three layer structure including an ONO struture. Gate 207 can be a metal gate or a conductive material different from a metal such as a doped semiconductor, such as but not limited to, doped polysilicon. Conductivity types, such as n-type and p-type, of various regions of transistor structure 200 can depend on the application for transistor structure 200.

Channel structure 205 can be implemented by different materials or structures. Channel structure 205 can be an epitaxial semiconductor. Channel structure 205 can be a recrystallized poly-semiconductor. For example, channel structure 205 can be, but is not limited to, epitaxial silicon. Channel structure 205 can be, but is not limited to, recrystallized polysilicon. Other semiconductor material, such as but not limited to gallium phosphide (GaP), can be used for channel structure 205.

A dielectric region 210 can extend from channel structure 205 downward into the substrate 202 and can be disposed between source 203 and drain 204 to reduce leakage current paths between source 203 and drain 204. Dielectric region 210 can be structured without conductive material or semiconductive material within the dielectric region, that is, dielectric region 210 can be structured completely as a dielectric. Dielectric region 210 can be realized as multiple dielectric materials or as one dielectric material. Dielectric region 210 can be implemented with various materials. Dielectric region 210 can include an electrically insulating oxide, such as but not limited to silicon oxide.

Dielectric region 210 can extend downward into substrate 202 to a level lower than a level at which source 203 extends into substrate 202 and lower than a level at which drain 204 extends into substrate 202. With dielectric region 210 extending to such a level, a sub-surface conduction path between source 203 and drain 204 is relatively long having a relatively large resistance substantially reducing or effectively eliminating leakage current.

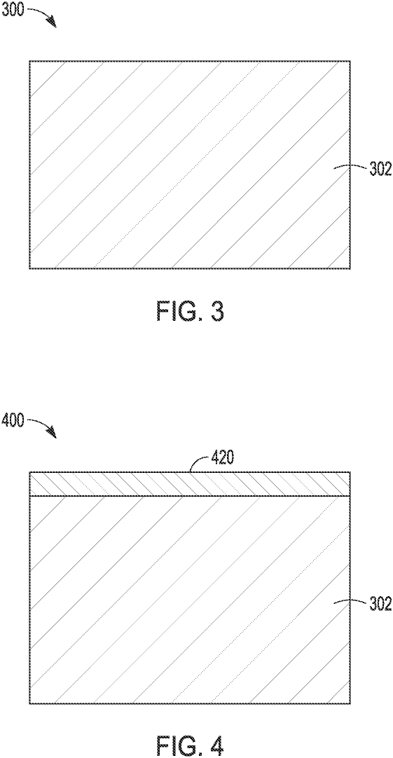

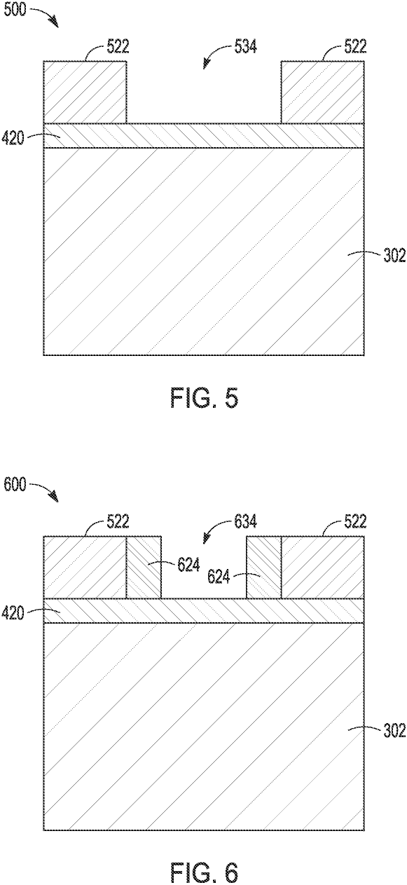

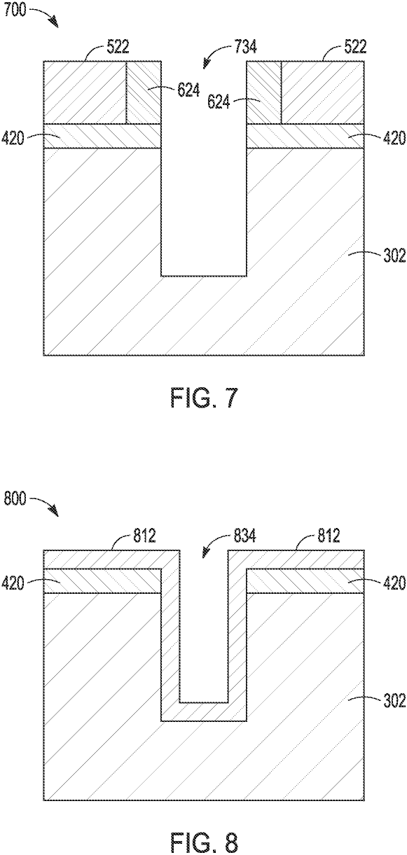

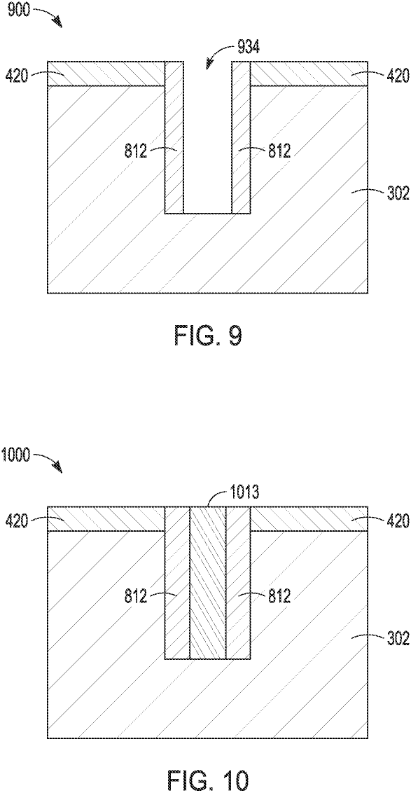

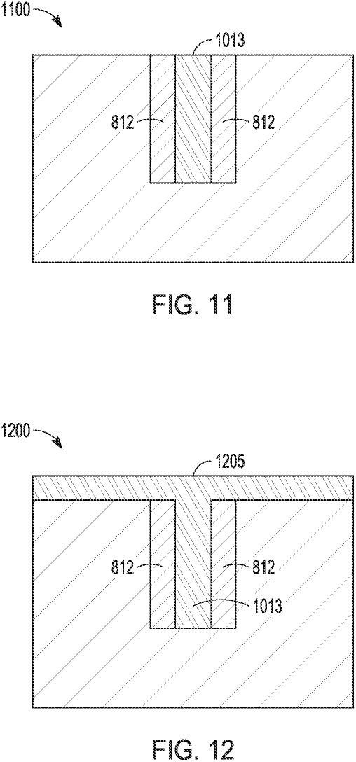

FIGS. 3 - 13 illustrate features of an embodiment of an example method of forming a transistor. FIG. 3 shows a cross-sectional view of a section of a substrate 302 of a structure 300 on which a channel structure of a transistor is to be constructed with a gate located above the channel structure. Substrate 302 can be a silicon substate or other substrate for an integrated circuit having one or more transistors. FIG. 4 shows a cross-sectional view of a structure 400 after a nitride layer 420 has been formed on the surface of the structure 300 of FIG. 3. Nitride layer 420 is formed as a processing layer that can be later removed in one or more processing steps. Nitride layer 420 can be formed by a suitable deposition process such as, but not limited to, chemical vapor deposition (CVD), atomic layer deposition (ALD), variations of CVD and ALD, a spin-on technique, or other technique. Materials other than a nitride may be used. The material and fabrication processes can be selected to meet the architecture of the transistor being formed or the device in which the transistor is being formed. In addition, deposition techniques can be used that are typical for the material being formed, the dimensions of the material being formed, and the architecture in which the material is being formed.

FIG. 5 shows a cross-sectional view of a structure 500 after a gate mask 522 has been formed on nitride layer 420 of structure 400 of FIG. 4. Gate mask 522 can be negative developed photoresist to form an opening 534 within gate mask 522. FIG. 6 shows a cross-sectional view of a structure 600 after an oxide spacer 624 has been formed including a spacer etch changing opening 534 to an opening 634 above nitride layer 420 of structure 500 of FIG. 5.

FIG. 7 shows a cross-sectional view of a structure 700 after nitride layer 420 of structure 600 of FIG. 6 has been punched in the opening 634 forming an opening 734 into substrate 302. The forming of opening 734 can include a dry etch. With substrate 302 having silicon material, the constituents for the dry etch can be selected to dry etch silicon. For example, silicon can be dry etched in a range of about 50 nm to 100 nm. The etch dimensions can be selected according to the architecture of the transistor being formed and the materials used.

FIG. 8 shows a cross-sectional view of a structure 800 after further processing of structure 700 of FIG. 7. Oxide spacer 624 and gate mask 522 have been stripped. In the stripping process, nitride layer 420 may be reduced. A dielectric 812 has been formed on the remaining nitride layer 420 and in the opening 734 of structure 700 covering the bottom of opening 734, changing the opening 734 to an opening 834 of structure 800. Dielectric 812 can be an oxide, such as but not limited to silicon oxide or a high k oxide, or an insulating nitride. Dielectric 812 can be formed having a thickness of approximately three to four nanometers. Dielectric 812 can be formed with other thickness. Dielectric 812 can be formed by any suitable deposition process . FIG. 9 shows a cross-sectional view of a structure 900 after punching dielectric 812 of structure 800 of FIG. 8 to remove the dielectric at the bottom surface of opening 834, forming opening 934 extending to substrate 302 with sidewalls of opening 934 being dielectric 812 that was not removed in the process of removing dielectric 812 from the bottom horizontal surface of opening 834.

FIG. 10 shows a cross-sectional view of a structure 1000 after forming crystalline material 1013 in opening 934 of structure 900 of FIG. 9. Crystalline material 1013 can fill opening 934 such that crystalline material 1013 contacts dielectric 812 as shown in FIG. 10. Crystalline material 1013 can be formed by epitaxially growing a semiconductor material. Crystalline material 1013 can be formed by forming a polycrystalline semiconductor material and recrystallizing the formed polycrystalline semiconductor material. The semiconductor material can be, but is not limited to, silicon.

FIG. 11 shows a cross-sectional view of a structure 1100 after stripping nitride layer 420 of structure 1000 of FIG. 10 and cleaning the surface resulting from the stripping process. The cleaning can include performing a chemical mechanical planarization (CMP) process to the surface. The cleaning may be conducted in some embodiments as an optional procedure.

FIG. 12 shows a cross-sectional view of a structure 1200 after forming a crystalline layer 1205 on the surface of structure 1100 of FIG. 11, where the crystalline layer 1205 is formed as a channel structure. Crystalline layer 1205 can be formed by epitaxially growing a semiconductor material. Crystalline layer 1205 can be formed by forming a polycrystalline semiconductor material and recrystallizing the formed polycrystalline semiconductor material. The semiconductor material can be, but is not limited to, silicon. For example, the material of crystalline layer 1205 can be gallium phosphide (GaP). The selection of the material for a channel structure can depend on other considerations for a transistor in an integrated circuit. For example, selection of GaP can be made if gate induced drain leakage (GIDL) is a primary concern.

FIG. 13 shows a cross-sectional view of a structure 1300 that incudes structure 1200 of FIG. 11, formed as discussed with respect to FIGS. 3-12. While FIGS. 3-12 illustrated formation of a portion of a transistor, structure 1300 shows MOSFET formation having structure 1200 with crystalline layer 1205 formed as its channel structure, with a dielectric region extending from crystalline layer 1205, where the dielectric region includes crystalline material 1013 encompassed by dielectric 812. A source region 1303 and a drain region 1304 can be formed coupled to crystalline layer 1205. A LDD 1308 can be formed between source region 1303 and crystalline layer 1205 and a LDD 1309 can be formed between drain region 1304 and crystalline layer 1205. A gate dielectric 1306 can be formed on crystalline layer 1205 and a gate 1307 can be formed on gate dielectric 1306. Source region 1303, drain region 1304, LDD 1308, LDD 1309, gate dielectric 1306, and gate 1307 can be formed using conventional CMOS processing techniques and materials, including conventional HV CMOS formation techniques. The procedures of FIGS. 3-12 can be used in forming transistor structures different from structure 1300. For example, these procedures can be used in forming floating gate transisitors, transistors with charge trap structures, or other similar transistors.

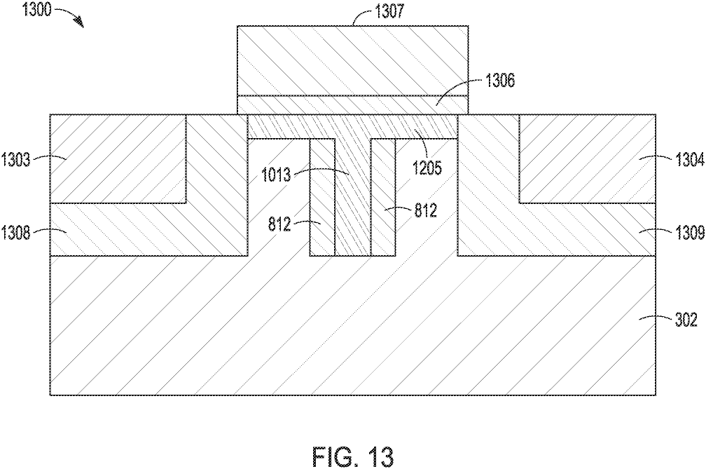

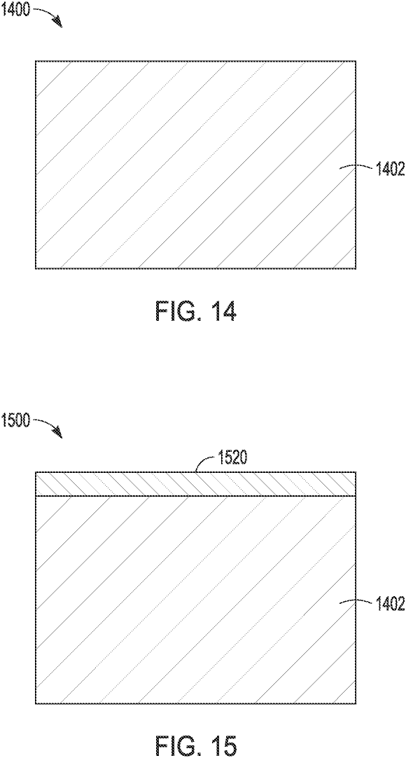

FIGS. 14 - 23 illustrate features of an embodiment of an example method of forming a transistor to address sub-surface conduction issues under similar principles as the transistor formed by the method of FIGS. 3-13. FIG. 14 shows a cross-sectional view of a section of a substrate 1402 of a structure 1400 on which a channel structure of a transistor is to be constructed with a gate located above the channel structure. Substrate 1402 can be a silicon substrate or other substrate for an integrated circuit having one or more transistors. FIG. 15 shows a structure 1500 after a nitride layer 1520 has been formed on the surface of the structure 1400 of FIG. 14. Nitride layer 1520 is formed as a processing layer that can be later removed in one or more processing steps. Nitride layer 1520 can be formed by a suitable deposition process such as, but not limited to, CVD, ALD, variations of CVD and ALD, a spin-on technique, or other technique. Materials other than a nitride may be used. The material and fabrication processes can be selected to meet the architecture of the transistor being formed or the device in which the transistor is being formed. In addition, deposition techniques can be used that are typical for the material being formed, the dimensions of the material being formed, and the architecture in which the material is being formed.

FIG. 16 shows a cross-sectional view of a structure 1600 after a gate mask 1622 has been formed on nitride layer 1520 of structure 1500 of FIG. 15. Gate mask 1622 can be negative photoresist developed to form an opening 1634 within gate mask 1622. FIG. 17 shows a cross-sectional view of a structure 1700 after an oxide spacer 1724 has been formed including a spacer etch changing opening 1634 to an opening 1734 above nitride layer 1520 of structure 1600 of FIG. 16.

FIG. 18 shows a cross-sectional view of a structure 1800 after nitride layer 1520 of structure 1700 of FIG. 7 has been punched in the opening 1734 forming an opening 1834 into substrate 1402. The forming of opening 1834 can include a dry etch. With substrate 1402 having silicon material, the constituents for the dry etch can be selected to dry etch silicon. For example, silicon can be dry etched in a range of about 50 nm to 100 nm. The etch dimensions can be selected according to the architecture of the transistor being formed and the materials used.

FIG. 19 shows a cross-sectional view of a structure 1900 after further processing of structure 1800 of FIG. 18. Oxide spacer 1724 and gate mask 1622 have been stripped. In the stripping process, nitride layer 1520 may be reduced. A dielectric 1910 has been formed on the remaining nitride layer 1520 and in the opening 1834 of structure 1800 covering the bottom of opening 1834. Dielectric 1910 can be an oxide, such as but not limited to silicon oxide or a high k oxide, or an insulating nitride. Dielectric 1910 can be formed by any suitable deposition process. Dielectric 1910 can be formed in a two step process such as first forming dielectric 1910 on the remaining nitride layer 1520 and in the opening 1834 without completely filling opening 1834 and, second, filing opening 1834 with dielectric material. In the two step process, the second dielectric material formed completely filling opening 1834 can be a material the same as or different from material of dielectric 1910.

FIG. 20 shows a cross-sectional view of a structure 2000 after removing dielectric 1910 disposed on nitride layer 1520 of FIG. 19. FIG. 21 shows a cross-sectional view of a structure 2100 after stripping nitride layer 1520 of structure 2000 of FIG. 20 and cleaning the surface the surface resulting from the stripping process. The cleaning can include performing a CMP process to the surface. The cleaning may be conducted in some embodiments as an optional procedure. Depending on the materials for dielectric 1910 and nitride layer 1520, the horizontal structure of dielectric 1910 disposed on nitride layer 1520 and nitride layer 1520 can be removed in a common procedure.

FIG. 22 shows a cross-sectional view of a structure 2200 after forming a crystalline layer 2205 on the surface of structure 2100 of FIG. 21, where the crystalline layer 2205 is formed as a channel structure. Crystalline layer 2205 can be formed by epitaxially growing a semiconductor material. Crystalline layer 2205 can be formed by forming a polycrystalline semiconductor material and recrystallizing the formed polycrystalline semiconductor material. The semiconductor material can be, but is not limited to, silicon. For example, the material of crystalline layer 2205 can be gallium phosphide (GaP). The selection of the material for a channel structure can depend on other considerations for a transistor in an integrated circuit. For example, selection of GaP can be made if gate induced drain leakage (GIDL) is a primary concern.

FIG. 23 shows a cross-sectional view of a structure 2300 that incudes structure 2200 of FIG. 22, formed as discussed with respect to FIGS. 14-22. While FIGS. 14-22 illustrated formation of a portion of a transistor, structure 2300 shows MOSFET formation having structure 2200 with crystalline layer 2205 formed as its channel structure with a dielectric 1910 extending from crystalline layer 2205. A source region 2303 and a drain region 2304 can be formed coupled to crystalline layer 2205. A LDD 2308 can be formed between source region 2303 and crystalline layer 2205 and a LDD 2309 can be formed between drain region 2304 and crystalline layer 2205. A gate dielectric 2306 can be formed on crystalline layer 2205 and a gate 2207 can be formed on gate dielectric 2306. Source region 2303, drain region 2304, LDD 2308, LDD 2309, gate dielectric 2306, and gate 2207 can be formed using conventional CMOS processing techniques and materials, including conventional HV CMOS formation techniques. The procedures of FIGS. 14-22 can be used in forming transistor structures different from structure 2300. For example, these procedures can be used in forming floating gate transisitors, transistors with charge trap structures, or other similar transistors.

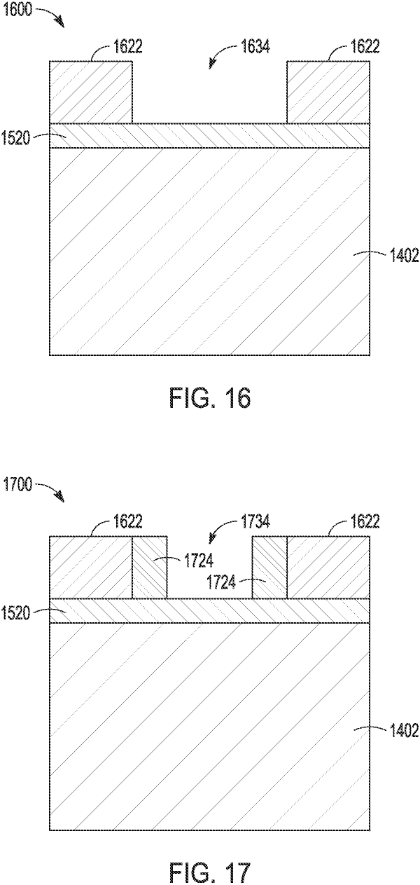

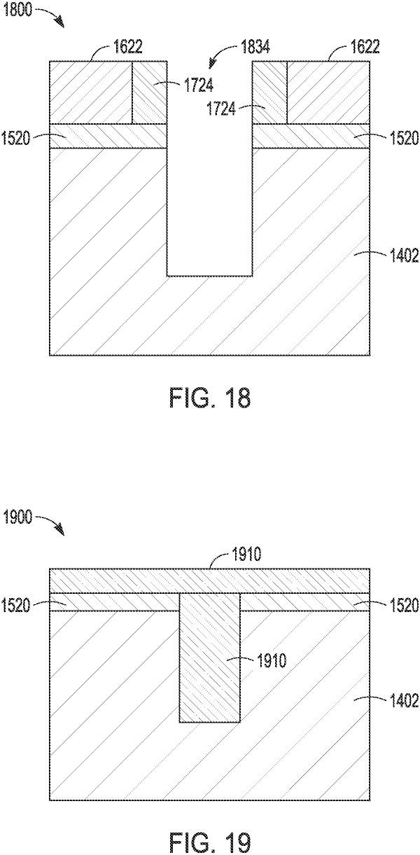

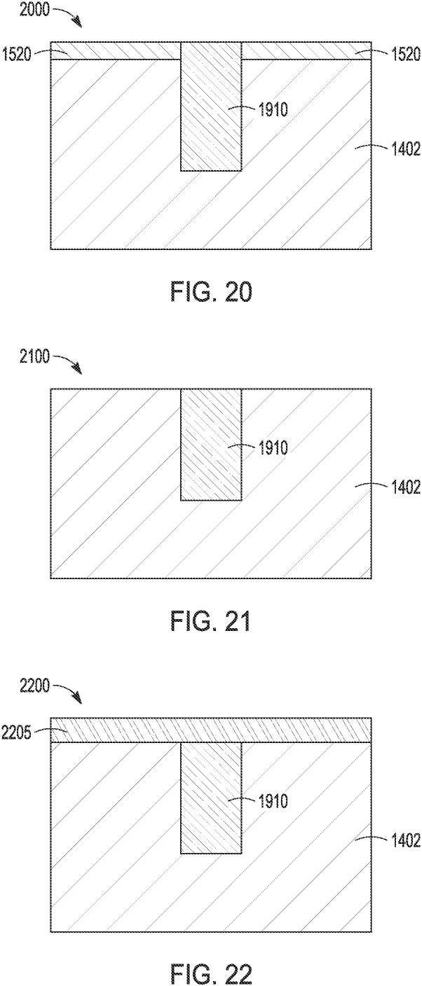

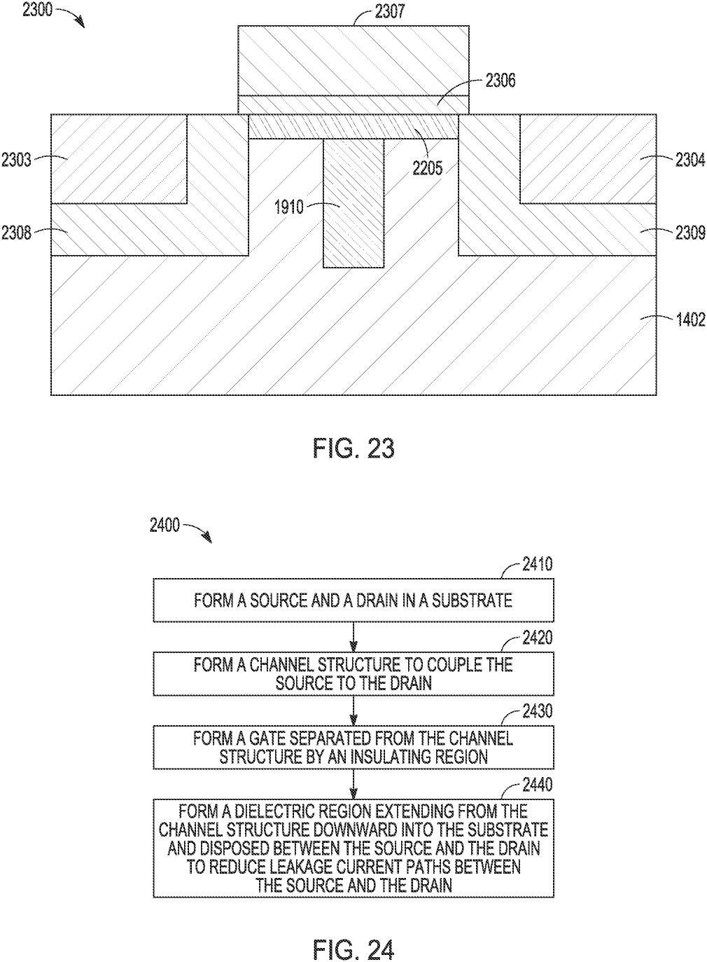

FIG. 24 is a flow diagram of features of an embodiment of an example method 2400 of forming a transistor. At 2410, a source and a drain are formed in a substrate. At 2420, a channel structure is formed to couple the source to the drain. At 2430, a gate is formed separated from the channel structure by an insulating region. At 2440, a dielectric region is formed extending from the channel structure downward into the substrate and disposed between the source and the drain to reduce leakage current paths between the source and the drain. The features of example method 2400 can be performed in an order appropriate for an integrated circuit in which the transistor is being formed.

Variations of method 2400 or methods similar to method 2400 can include a number of different embodiments that may be combined depending on the application of such methods, the architecture of the transistors being formed, and/or the architecture of the system in which such transistors are implemented. Such variations can include forming the dielectric region by forming a crystalline semiconductor region within dielectric material. Such variations can include forming the dielectric region by forming the dielectric region without conductive material or semiconductive material.

Variations of method 2400 or methods similar to method 2400 can include forming the channel structure by growing semiconductor material epitaxially on the substrate. Variations can include forming the channel structure by depositing a polycrystalline semiconductor material on the substrate and performing a recrystallization of the polycrystalline semiconductor material.

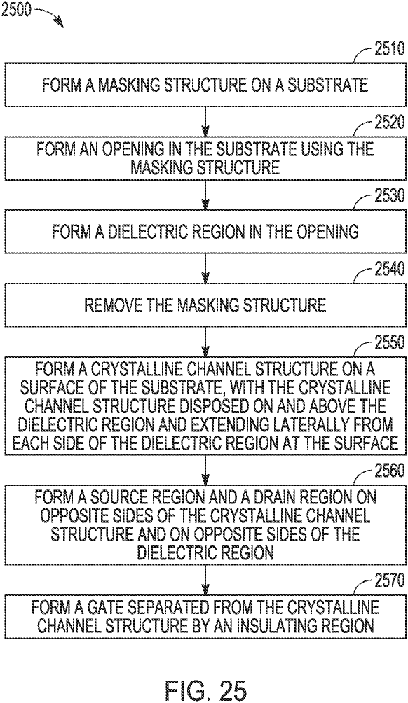

FIG. 25 is a flow diagram of features of an embodiment of an example method 2500 of forming a transistor. At 2510, a masking structure is formed on a substrate. At 2520, an opening is formed in the substrate using the masking structure. At 2530, a dielectric region is formed in the opening. At 2540, the masking structure is removed. At 2550, a crystalline channel structure is formed on a surface of the substrate, with the crystalline channel structure disposed on and above the dielectric region and extending laterally from each side of the dielectric region at the surface. At 2560, a source region and a drain region are formed on opposite sides of the crystalline channel structure and on opposite sides of the dielectric region. At 2570, a gate is formed separated from the crystalline channel structure by an insulating region. The features of example method 2500 can be performed in an order appropriate for an integrated circuit in which the transistor is being formed.

Variations of method 2500 or methods similar to method 2500 can include a number of different embodiments that may be combined depending on the application of such methods, the architecture of the transistors being formed, and/or the architecture of the system in which such transistors are implemented. Such variations can include forming the dielectric region in the opening by depositing dielectric material on walls of the opening, reducing the opening. A portion of the dielectric material on a bottom wall of the opening can be etched, exposing the substrate in the reduced opening. A crystalline semiconductor can be formed in the reduced opening to the substrate. Variations can include forming the dielectric region by depositing dielectric material in the opening and filling the opening

Variations of method 2500 or methods similar to method 2500 can include forming the masking structure on the substrate by depositing a nitride on the substrate; forming a gate mask on the nitride, depositing an oxide spacer on a side wall of the gate mask; and etching the oxide spacer, providing an initial opening for forming the opening in the substrate. Forming the masking structure on the substrate can include removing the gate mask and oxide spacer before forming the dielectric region in the opening; and removing the nitride after forming the dielectric region in the opening. A temporary structure, resulting from removing the nitride, can be cleaned before forming the crystalline channel structure on the surface of the substrate.

Variations of method 2500 or methods similar to method 2500 can include forming the crystalline channel structure on the surface of the substrate by growing silicon epitaxially on the substrate. Variations can include forming the crystalline channel structure on the surface of the substrate by depositing polysilicon on the substrate and performing a recrystallization of the polysilicon. Variations of method 2500 or methods similar to method 2500 can include forming a first lightly-doped drain between the source region and the crystalline channel structure and forming a second lightly-doped drain between the drain region and the crystalline channel structure.

In various embodiments, a transistor can comprise a source and a drain in a substrate, with a channel structure to couple the source to the drain, and a gate separated from the channel structure by an insulating region. The transistor can include a dielectric region extending from the channel structure downward into the substrate and disposed between the source and the drain to reduce leakage current paths between the source and the drain. Such a transistor can be designed with various different features. The dielectric region can include a crystalline semiconductor region within dielectric material. The dielectric region can be structured without conductive material or semiconductive material within the dielectric region. The crystalline semiconductor region can include epitaxial silicon, and the dielectric material can include an electrically insulating oxide. Material of the channel structure and material of the crystalline semiconductor region can have a common composition. The dielectric region can extend downward into the substrate to a level lower than a level at which the source extends into the substrate and lower than a level at which the drain extends into the substrate.

A machine-readable storage device storing instructions, that when executed by one or more processors, can cause a machine to perform operations, where the instructions include operations to simulate the transistor or components of the transistor, or to simulate performance of the operations of the transistor and methods disclosed herein.

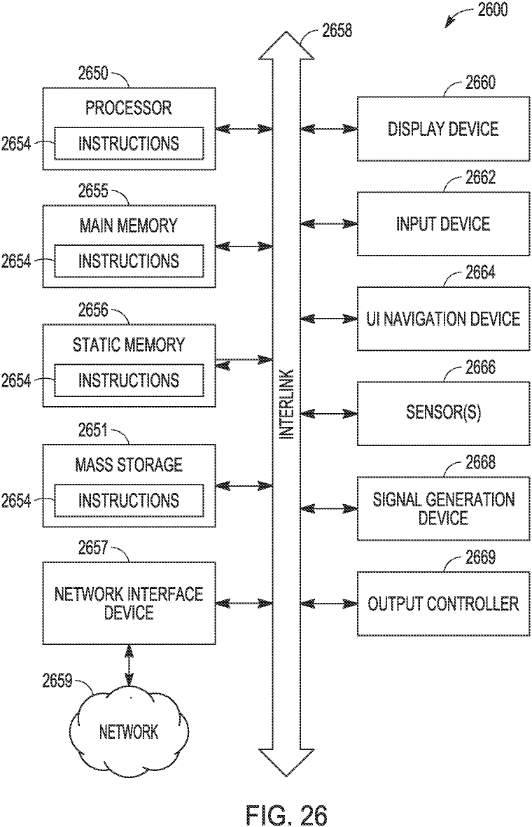

FIG. 26 illustrates a block diagram of an example machine 2600 upon which any one or more of the techniques (e.g., methodologies) discussed herein may perform. In alternative embodiments, the machine 2600 may operate as a standalone device or may be connected (e.g., networked) to other machines. In a networked deployment, the machine 2600 may operate in the capacity of a server machine, a client machine, or both in server-client network environments. In an example, the machine 2600 may act as a peer machine in peer-to-peer (P2P) (or other distributed) network environment. The machine 2600 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations. The example machine 2600 can include devices having one or more transistors having a modified channel region similar to the transistors of FIG. 1 or FIG. 2.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation.

The machine 2600 may include a hardware processor 2650 (e.g., a CPU, a GPU, a hardware processor core, or any combination thereof), a main memory 2655, and a static memory 2656, some or all of which may communicate with each other via an interlink 2658 (e.g., bus). The machine 2600 may further include a display device 2660, an input device 2662, which can be an alphanumeric input device (e.g., a keyboard), and a user interface (UI) navigation device 2664 (e.g., a mouse). In an example, the display device 2660, input device 2662, and UI navigation device 2664 may be a touch screen display. The machine 2600 may additionally include a mass storage device (e.g., drive unit) 2651, a signal generation device 2668, a network interface device 2657, and one or more sensors 2666, such as a global positioning system (GPS) sensor, compass, accelerometer, or other sensor. The machine 2600 may include an output controller 2669, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The machine 2600 can store one or more sets of data structures or instructions 2654 (e.g., software) embodying or utilized by the machine 2600 to perform any one or more of the techniques or functions for which the machine 2600 is designed. The instructions 2654 may also reside, completely or at least partially, within the main memory 2655, within static memory 2656, or within the hardware processor 2650 during execution thereof by the machine 2600.

The instructions 2654 (e.g., software, programs, an operating system (OS), etc.) or other data can be stored on the mass storage device 2651 or can be accessed by the main memory 2655 for use by the hardware processor 2650. The main memory 2655 (e.g., DRAM) is typically fast, but volatile, and thus a different type of storage than the mass storage device 2651 (e.g., an SSD), which is suitable for long-term storage, including while in an “off” condition. The instructions 2654 or data in use by a user or the machine 2600 are typically loaded in the main memory 2655 for use by the hardware processor 2650. When the main memory 2655 is full, virtual space from the mass storage device 2651 can be allocated to supplement the main memory 2655, however, because the mass storage device 2651 is typically slower than the main memory 2655, and write speeds are typically at least twice as slow as read speeds, use of virtual memory can greatly reduce user experience due to storage device latency (in contrast to the main memory 2655, e.g., DRAM). Further, use of the mass storage device 2651 for virtual memory can greatly reduce the usable lifespan of the mass storage device 2651.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, embedded MMC (eMMC™) devices are attached to a circuit board and considered a component of the host device, with read speeds that rival Serial Advanced Technology Attachment (SATA)-based SSD devices. However, demand for mobile device performance continues to increase, such as to fully enable virtual or augmented-reality devices, utilize increasing networks speeds, etc. In response to this demand, storage devices have shifted from parallel to serial communication interfaces. Universal Flash Storage (UFS) devices, including controllers and firmware, communicate with a host device using a low-voltage differential signaling (LVDS) serial interface with dedicated read/write paths, further advancing greater read/write speeds.

The instructions 2654 can be transmitted or received over a network 2659 using a transmission medium via signal generation device 2668 or network interface device 2657 utilizing any one of a number of transfer protocols (e.g., frame relay, Internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, and peer-to-peer (P2P) networks, among others. In an example, the signal generation device 2668 or network interface device 2657 may include one or more physical jacks (e.g., Ethernet, coaxial, or phone jacks) or one or more antennas to connect to the network 2659. In an example, the signal generation device 2668 or network interface device 2657 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of carrying instructions to and for execution by the machine 2600, and includes instrumentalities to propagate digital or analog communications signals to facilitate communication of such instructions, which instructions may be implemented by software.

The following are example embodiments of devices and methods, in accordance with the teachings herein.

An example method 1 of forming a transistor can comprise: forming a source and a drain in a substrate; forming a channel structure to couple the source to the drain; forming a gate separated from the channel structure by an insulating region; and forming a dielectric region extending from the channel structure downward into the substrate and disposed between the source and the drain to reduce leakage current paths between the source and the drain.

An example method 2 of forming a transistor can include features of example method 1 of forming a transistor and can include forming the dielectric region to include forming a crystalline semiconductor region within dielectric material.

An example method 3 of forming a transistor can include features of any of the preceding example methods of forming a transistor and can include forming the dielectric region to include forming the dielectric region without conductive material or semiconductive material.

An example method 4 of forming a transistor can include features of any of the preceding example methods of forming a transistor and can include forming the channel structure to include growing semiconductor material epitaxially on the substrate.

An example method 5 of forming a transistor can include features of any of the preceding example methods of forming a transistor and can include forming the channel structure to include depositing a polycrystalline semiconductor material on the substrate and performing a recrystallization of the polycrystalline semiconductor material.

In an example method 6 of forming a transistor, any of the example methods 1 to 5 of forming a transistor may be performed in forming an electronic memory apparatus further comprising a host processor and a communication bus extending between the host processor and the memory device.

In an example method 7 of forming a transistor, any of the example methods 1 to 6 of forming a transistor may be modified to include operations set forth in any other of example methods 1 to 6 of forming a transistor.

In an example method 8 of forming a transistor, any of the example methods 1 to 9 of forming a transistor may be implemented at least in part through use of instructions stored as a physical state in one or more machine-readable storage devices.

An example method 9 of forming a transistor can include features of any of the preceding example methods 1 to 8 of forming a transistor and can include performing functions associated with any features of example memory devices and systems having memory devices discussed herein.

An example machine-readable storage device 1 storing instructions, that when executed by one or more processors, cause a machine to perform operations, can comprise instructions to perform functions associated with any features of example memory devices and systems having transistor devices discussed herein or perform methods associated with any features of example methods 1 to 9.

An example method 10 of forming a transistor can comprise: forming a masking structure on a substrate; forming an opening in the substrate using the masking structure; forming a dielectric region in the opening; and removing the masking structure. The example method 10 also comprises forming a crystalline channel structure on a surface of the substrate, with the crystalline channel structure disposed on and above the dielectric region and extending laterally from each side of the dielectric region at the surface; forming a source region and a drain region on opposite sides of the crystalline channel structure and on opposite sides of the dielectric region; and forming a gate separated from the crystalline channel structure by an insulating region

An example method 11 of forming a transistor can include features of example method 10 of forming a transistor and can include forming the dielectric region to include: depositing dielectric material on walls of the opening, reducing the opening; etching a portion of the dielectric material on a bottom wall of the opening, exposing the substrate in the reduced opening; and forming crystalline semiconductor in the reduced opening to the substrate.

An example method 12 of forming a transistor can include features of any of the example methods 10 or 11 of forming a transistor and can include forming the dielectric region to include depositing dielectric material in the opening, filling the opening.

An example method 13 of forming a transistor can include features of any of the example methods 10 to 12 of forming a transistor and can include forming the masking structure on the substrate to include: depositing a nitride on the substrate; forming a gate mask on the nitride; depositing an oxide spacer on a side wall of the gate mask; and etching the oxide spacer, providing an initial opening for forming the opening in the substrate.

An example method 14 of forming a transistor can include features of example method 13 and features of any of the example methods 10 to 13 of forming a transistor and can include forming the masking structure on the substrate to include removing the gate mask and oxide spacer before forming the dielectric region in the opening and removing the nitride after forming the dielectric region in the opening.

An example method 15 of forming a transistor can include features of example method 14 and features of any of the example methods 10 to 14 of forming a transistor and can include cleaning a temporary structure, resulting from removing the nitride, before forming the crystalline channel structure on the surface of the substrate.

An example method 16 of forming a transistor can include features of any of the example methods 10 to 15 of forming a transistor and can include forming the crystalline channel structure on the surface of the substrate to include growing silicon epitaxially on the substrate.

An example method 17 of forming a transistor can include features of any of the example methods 10 to 16 of forming a transistor and can include forming the crystalline channel structure on the surface of the substrate to include depositing polysilicon on the substrate and performing a recrystallization of the polysilicon.

An example method 18 of forming a transistor can include features of any of the example methods 10 to 17 of forming a transistor and can include forming a first lightly-doped drain between the source region and the crystalline channel structure and forming a second lightly-doped drain between the drain region and the crystalline channel structure.

In an example method 19 of forming a transistor, any of the example methods 10 to 18 of forming a transistor may be performed in forming an electronic memory apparatus further comprising a host processor and a communication bus extending between the host processor and the memory device.

In an example method 20 of forming a transistor, any of the example methods 10 to 19 of forming a transistor may be modified to include operations set forth in any other of example methods 1 to 19 of forming a transistor.

In an example method 21 of forming a transistor, any of the example methods 10 to 20 of forming a transistor may be implemented at least in part through use of instructions stored as a physical state in one or more machine-readable storage devices.

An example method 22 of forming a transistor can include features of any of the preceding example methods 10 to 21 of forming a transistor and can include performing functions associated with any features of example memory devices and systems having memory devices discussed herein.

An example machine-readable storage device 2 storing instructions, that when executed by one or more processors, cause a machine to perform operations, can comprise instructions to perform functions associated with any features of example memory devices and systems having transistor devices discussed herein or perform methods associated with any features of example methods 10 to 22.

An example transistor 1 can comprise: a source and a drain in a substrate with a channel structure to couple the source to the drain. A gate of example transistor 1 is separated from the channel structure by an insulating region. The example transistor 1 comprises a dielectric region extending from the channel structure downward into the substrate and disposed between the source and the drain to reduce leakage current paths between the source and the drain.

An example transistor 2 can include features of example transistor 1 and can include the dielectric region having a crystalline semiconductor region within dielectric material.

An example transistor 3 can include features of example transistor 2 can include the crystalline semiconductor region including epitaxial silicon and the dielectric material including an electrically insulating oxide.

An example transistor 4 can include features of example transistor 2 and any of the preceding example transistors and can include material of the channel structure and material of the crystalline semiconductor region having a common composition.

An example transistor 5 can include features of any of the preceding example transistors and can include the dielectric region being structured without conductive material or semiconductive material within the dielectric region.

An example transistor 6 can include features of any of the preceding example transistors and can include the dielectric region extending downward into the substrate to a level lower than a level at which the source extends into the substrate and lower than a level at which the drain extends into the substrate.

In an example transistor 7, any of the transistors of example transistors 1 to 6 may include transistors incorporated into an electronic memory apparatus further comprising a host processor and a communication bus extending between the host processor and the transistor.

In an example transistor 8, any of the transistors of example transistors 1 to 7 may be modified to include any structure presented in another of example transistor 1-7.

In an example transistor 9, any apparatus associated with the transistors of example transistors 1 to 8 may further include a machine-readable storage device configured to store instructions as a physical state, wherein the instructions may be used to perform one or more operations of the apparatus.

In an example transistor 10, any of the transistors of example transistors 1 to 9 may be formed in accordance with any of the methods of the following example methods 1 to 22.

An example machine-readable storage device 3 storing instructions, that when executed by one or more processors, cause a machine to perform operations, can comprise instructions to perform functions associated with any features of example memory devices and systems having transistor devices discussed herein.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description

What is claimed is:

1. A transistor comprising:
a source and a drain in a substrate;
a channel structure to couple the source to the drain;
a gate separated from the channel structure by an insulating region; and
a dielectric region extending from the channel structure downward into the substrate and disposed between the source and the drain to reduce leakage current paths between the source and the drain.

2. The transistor of claim 1, wherein the dielectric region includes a crystalline semiconductor region within dielectric material.

3. The transistor of claim 2, wherein the crystalline semiconductor region includes epitaxial silicon, and the dielectric material includes an electrically insulating oxide.

4. The transistor of claim 2, wherein material of the channel structure and material of the crystalline semiconductor region have a common composition.

5. The transistor of claim 1, wherein the dielectric region is structured without conductive material or semiconductive material within the dielectric region.

6. The transistor of claim 1, wherein the dielectric region extends downward into the substrate to a level lower than a level at which the source extends into the substrate and lower than a level at which the drain extends into the substrate.

7. A method of forming a transistor, the method comprising:
forming a source and a drain in a substrate;
forming a channel structure to couple the source to the drain;
forming a gate separated from the channel structure by an insulating region; and
forming a dielectric region extending from the channel structure downward into the substrate and disposed between the source and the drain to reduce leakage current paths between the source and the drain.

8. The method of claim 7, wherein forming the dielectric region includes forming a crystalline semiconductor region within dielectric material.

9. The method of claim 7, wherein forming the dielectric region includes forming the dielectric region without conductive material or semiconductive material.

10. The method of claim 7, wherein forming the channel structure includes growing semiconductor material epitaxially on the substrate.

11. The method of claim 7, wherein forming the channel structure includes: depositing a polycrystalline semiconductor material on the substrate; and performing a recrystallization of the polycrystalline semiconductor material.

12. A method of forming a transistor, the method comprising:
forming a masking structure on a substrate;
forming an opening in the substrate using the masking structure;
forming a dielectric region in the opening;
removing the masking structure;
forming a crystalline channel structure on a surface of the substrate, with the crystalline channel structure disposed on and above the dielectric region and extending laterally from each side of the dielectric region at the surface; and
forming a source region and a drain region on opposite sides of the crystalline channel structure and on opposite sides of the dielectric region; and
forming a gate separated from the crystalline channel structure by an insulating region.

13. The method of claim 12, wherein forming the dielectric region includes:
depositing dielectric material on walls of the opening, reducing the opening;
etching a portion of the dielectric material on a bottom wall of the opening, exposing the substrate in the reduced opening; and
forming a crystalline semiconductor in the reduced opening to the substrate.

14. The method of claim 12, wherein forming the dielectric region includes depositing dielectric material in the opening, filling the opening.

15. The method of claim 12, wherein forming the masking structure on the substrate includes:
depositing a nitride on the substrate;
forming a gate mask on the nitride;
depositing an oxide spacer on a side wall of the gate mask; and
etching the oxide spacer, providing an initial opening for forming the opening in the substrate.

16. The method of claim 15, wherein forming the masking structure on the substrate includes:
removing the gate mask and oxide spacer before forming the dielectric region in the opening; and
removing the nitride after forming the dielectric region in the opening.

17. The method of claim 16, wherein the method includes cleaning a temporary structure, resulting from removing the nitride, before forming the crystalline channel structure on the surface of the substrate.

18. The method of claim 12, wherein forming the crystalline channel structure on the surface of the substrate includes growing silicon epitaxially on the substrate.

19. The method of claim 12, wherein forming the crystalline channel structure on the surface of the substrate includes:
depositing polysilicon on the substrate; and
performing a recrystallization of the polysilicon.

20. The method of claim 12, wherein the method includes forming a first lightly-doped drain between the source region and the crystalline channel structure and forming a second lightly-doped drain between the drain region and the crystalline channel structure.
